(19) United States
(12) Patent Application Publication
(10) Pub. No.: US 2026/0068266 A1
(43) Pub. Date: Mar. 5, 2026

(54) SCALABLE III-N DEVICES WITH THRESHOLD VOLTAGE CONTROL

(71) Applicant: TEXAS INSTRUMENTS INCORPORATED, Dallas, TX (US)

(72) Inventor: Dong Seup Lee, Allen, TX (US)

(21) Appl. No.: 18/820,370

(22) Filed: Aug. 30, 2024

(51) Int. Cl. H01L 29/417; H01L 29/20; H01L 29/66; H01L 29/778

(52) U.S. Cl. CPC H10D 64/23; H10D 30/015; H10D 30/47; H10D 62/8503

(57) ABSTRACT

Semiconductor devices including scalable threshold voltage control are described. In one example, a semiconductor device comprises a semiconductor substrate including a source region, a gate region, a drain region, and a drain access region, where a heterojunction structure is disposed over the semiconductor substrate. The heterojunction structure includes a buffer layer over the semiconductor substrate and a barrier layer over the buffer layer. A p-doped III-N layer is disposed over the barrier layer. One or more tuning electrodes are disposed over the p-doped III-N layer. A gate electrode is disposed over the p-doped III-N layer having a gate contact area.

### FIELD OF THE DISCLOSURE

Disclosed implementations relate generally to the field of group III-N semiconductor devices and their fabrication.

### BACKGROUND

Group III nitride materials (also referred to as III-N materials) possess a unique combination of physical and electrical properties found to be beneficial in modern microelectronics and optoelectronics. Among these properties are wide bandgap, high saturated drift velocity and breakdown voltage, high thermal conductivity, robust chemical and thermal stability, etc. Due to these characteristics, III-N materials are being considered as promising materials for fabrication of powerful high-frequency transistors capable of functioning at high temperatures and in hostile environments. Whereas advances in III-N devices and their fabrication continue to grow apace, several lacunae remain, thereby requiring further innovation as will be set forth hereinbelow.

### SUMMARY

The following presents a simplified summary in order to provide a basic understanding of some examples of the present disclosure. This summary is not an extensive overview of the examples, and is neither intended to identify key or critical elements of the examples, nor to delineate the scope thereof. Rather, the primary purpose of the summary is to present some concepts of the present disclosure in a simplified form as a prelude to a more detailed description that is presented in subsequent sections further below.

In one example, a semiconductor device comprises a semiconductor substrate including a source region, a gate region, a drain region, and a drain access region, where a heterojunction structure is disposed over the semiconductor substrate. The heterojunction structure includes a buffer layer over the semiconductor substrate and a barrier layer over the buffer layer. A p-doped III-N layer is disposed over the barrier layer. One or more tuning electrodes are disposed over the p-doped III-N layer. A gate electrode is disposed over the p-doped III-N layer having a gate contact area. In some arrangements, an optional AlGaN capping layer may be disposed over the p-doped III-N layer.

In one example, a method of fabricating a III-N semiconductor device is disclosed. The method comprises, among others, forming a heterojunction structure over a semiconductor substrate including a source region, a gate region, a drain region, and a drain access region between the gate region and the drain region, the heterojunction structure including a buffer layer over the semiconductor substrate and a barrier layer over the buffer layer; forming a p-doped III-N layer over the barrier layer; forming a gate electrode over the p-doped III-N layer having a gate contact area; and forming one or more tuning electrodes over the p-doped III-N layer. In some arrangements, the one or more tuning electrodes may be formed concurrently with formation of source and drain electrodes in the source and drain regions, respectively. In some arrangements, the gate electrode may be formed before forming the source and drain electrodes. In some arrangements, the gate electrode may be formed after forming the source and drain electrodes. In some arrangements, the one or more tuning electrodes may be connected to a source, a ground or a reference node.

In one example, an integrated circuit (IC) is disclosed, which comprises a semiconductor substrate; a first III-N device formed in or over a first area of the semiconductor substrate; and a second III-N device formed in or over a second area of the semiconductor substrate. In some arrangements, the first III-N device includes a source region and a gate region of the first area; a first stack of III-N layer including a first heterojunction structure and a first p-doped III-N layer formed on the first heterojunction structure; a gate electrode having a first gate contact area disposed over the first p-doped III-N layer; and a first number of tuning electrodes over the first p-doped III-N layer. In some arrangements, the second III-N device includes a source region and a gate region of the second area; a second stack of III-N layer including a second heterojunction structure and a second p-doped III-N layer formed on the second heterojunction structure; a gate electrode having a second gate contact area disposed over the second p-doped III-N layer; and a second number of tuning electrodes over the second p-doped III-N layer. In some arrangements, the first number of tuning electrodes may be zero whereas the second number of tuning electrodes is not zero. In some arrangements, the first number of tuning electrodes and the second number of tuning electrodes may be the same. In some arrangements, the first gate contact area and the second gate contact area may be the same. In some arrangements, the first stack of III-N layer and the second stack of III-N layer of the IC may be formed concurrently.

### BRIEF DESCRIPTION OF THE DRAWINGS

Implementations of the present disclosure are illustrated by way of example, and not by way of limitation, in the Figures of the accompanying drawings. Different references to “an” or “one” implementation in this disclosure are not necessarily to the same implementation, and such references may mean at least one. Further, when a particular feature, structure, or characteristic is described in connection with an implementation, such feature, structure, or characteristic in connection with other implementations may be feasible whether or not explicitly described.

The accompanying drawings are incorporated into and form a part of the specification to illustrate one or more example implementations of the present disclosure. Various advantages and features of the disclosure are described in the following Detailed Description taken in connection with the appended claims and with reference to the attached drawing Figures in which:

FIG. 1A depicts a 3-dimensional (3D) schematic of a GaN device including one or more threshold tuning capacitive loads according to some examples of the present disclosure;

FIG. 1B depicts a cross-sectional view of the GaN device shown in FIG. 1A along a sectional plane through a gate;

FIG. 1C depicts a cross-sectional view of the GaN device shown in FIG. 1A along a sectional plane through an electrode operable as the tuning capacitive load;

FIG. 2 depicts an equivalent circuit representation of a GaN device including a threshold tuning capacitive load according to some examples;

FIGS. 3A-1 and 3A-2 depict drain-centered two-finger layouts of a representative GaN device where one or more tuning electrodes may be provided in a configurable architecture for tuning the threshold voltage of the device according to some examples;

FIG. 3B depicts a layout detail of a tuning electrode commonly coupled to a source of the GaN device shown in FIG. 3A-1;

FIGS. 3C-1 and 3C-2, 3D-1 and 3D-2, and 3E-1 and 3E-2 depict various layouts of GaN devices according to some additional and/or alternative examples of the present disclosure;

FIG. 4 depicts a relationship between threshold voltage and the ratio of tuning electrode contact area to gate contact area of a GaN device according to some examples; and FIG. 5 is a flowchart of a method of fabricating a semiconductor device including one or more GaN devices according to some examples of the present disclosure.

### DETAILED DESCRIPTION

Examples of the disclosure are described with reference to the attached Figures where like reference numerals are generally utilized to refer to like elements. The Figures are not drawn to scale and they are provided merely to illustrate examples. Numerous specific details, relationships, and methods are set forth below to provide an understanding of one or more examples. However, some examples may be practiced without such specific details. In other instances, well-known subsystems, components, structures and techniques have not been shown in detail in order not to obscure the understanding of the examples. Accordingly, the examples of the present disclosure may be practiced without such specific components.

Additionally, terms such as “coupled” and “connected,” along with their derivatives, may be used in the following description, claims, or both. It should be understood that these terms are not necessarily intended as synonyms for each other. “Coupled” may be used to indicate that two or more elements, which may or may not be in direct physical or electrical contact with each other, co-operate or interact with each other. “Connected” may be used to indicate the establishment of communication, i.e., a communicative relationship, between two or more elements that are coupled with each other. Further, in one or more examples set forth herein, generally speaking, an element, component or module may be configured to perform a function if the element may be programmed for performing or otherwise structurally arranged to perform that function.

Without limitation, examples of the present disclosure will be set forth below in the context of improving performance characteristics of semiconductor devices based on Group III nitride materials such as gallium nitride (GaN) devices.

GaN devices, e.g., GaN transistors, provide certain performance advantages over silicon, including lower on-state resistance (e.g., drain-source resistance or R_{DSON}), lower switching losses, and improved breakdown voltage, among others. GaN transistors include a hetero epitaxy structure with a junction between materials of different bandgaps (e.g., a heterojunction structure), such as aluminum gallium nitride (AlGaN) and gallium nitride, to provide a 2-dimensional electron gas (2DEG) formed within the AlGaN/GaN hetero epitaxy structure that is used for device operation—e.g., forming a channel of the GaN device. The 2-dimensional electron gas (2DEG) may be referred to as a 2DEG channel. Depletion mode (DMODE) GaN transistors are normally on, whereas enhancement mode (EMODE) GaN transistors are normally off. In some examples, EMODE GaN transistors include a gate stack with a p-type doped gallium nitride (p-GaN) layer that depletes the 2DEG beneath the gate at zero or negative gate bias. In some examples, the p-GaN layer may comprise a GaN layer doped with magnesium (Mg) or other p-type dopants. Applying a positive gate voltage, e.g., a threshold voltage, enhances the 2DEG under the gate and turns the EMODE GaN device on to allow current flow between the source and the drain.

In some examples, a GaN device may be formed with one or more GaN layers over a suitable semiconductor substrate, e.g., including a silicon substrate, where a portion of the GaN layers may form a heterojunction structure over the semiconductor substrate, with a p-GaN layer overlying the heterojunction structure for effectuating EMODE device functionality. As the GaN layers are formed in sequential epitaxial operations resulting in an epitaxial or “epi” stack over an area of the semiconductor substrate, the threshold voltage of the GaN devices to be formed in the area is generally fixed before the fabrication is complete. This is so because the threshold voltage of an EMODE device is mainly determined by the factors related to the structure and composition of the epi stack, e.g., percentage of Al content in the AlGaN barrier layer, thickness of the AlGaN barrier layer, dopant concentration and profile in the p-GaN layer, etc. Accordingly, the threshold voltages (V_{T} or V_{TH}) of GaN devices formed in or over a same epi stack generally tend to be substantially identical. However, having same threshold voltages can thwart efforts to integrate multiple GaN devices in a circuit where a range of V_{TH} values are desired, e.g., lower V_{TH} values for devices with high driving current, higher V_{TH} values for devices with low leakage, etc.

Examples of the present disclosure recognize the foregoing challenges and provide an architecture for fabricating GaN devices having different V_{TH} values on a same epi stack of the semiconductor substrate. In some arrangements, a configurable layout design is provided that facilitates the fabrication of tunable capacitive loads operable to modulate the behavior of gate electrodes of individual GaN devices in order to control V_{TH} values in a scalable manner. In some arrangements, the tunable capacitive loads may be provided as electrical contacts (e.g., Schottky contacts, ohmic contacts, rectifying contacts, non-rectifying contacts) to a p-GaN layer of the device, where the contacts may vary in size, number, placement, or in any combination, for regulating or otherwise adjusting the effect of a gate electrode formed on the p-GaN layer so as to alter the V_{TH} value of the device. Accordingly, such contacts may be referred to as tuning contacts or electrodes (or tunable contacts or electrodes) for purposes of examples herein. While the tuning contacts or electrodes for controlling an individual GaN device's threshold voltage may be fabricated at different stages of a process flow depending on implementation, some examples herein advantageously provide a layout design where the tuning contacts may be concurrently formed in a source contact formation stage so as to integrate tuning contact formation in a cost-effective manner. Whereas the examples herein may provide various structures, materials and processes that may engender these and other beneficial effects, no particular result is a requirement unless explicitly recited in a particular claim.

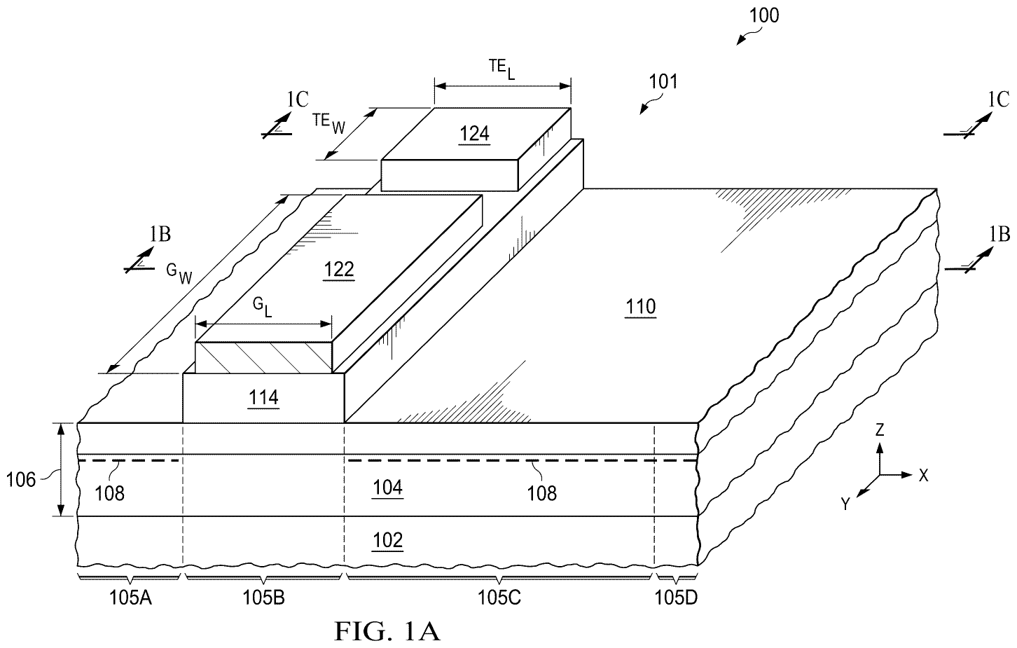

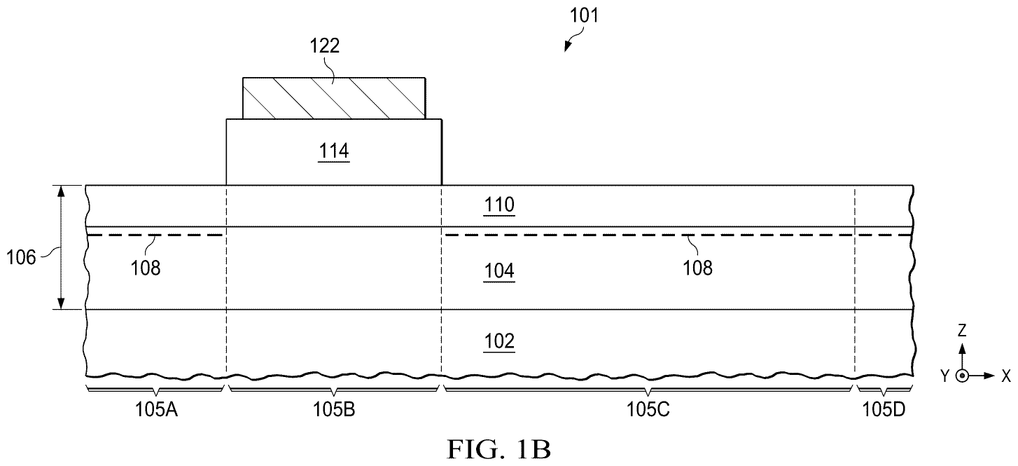

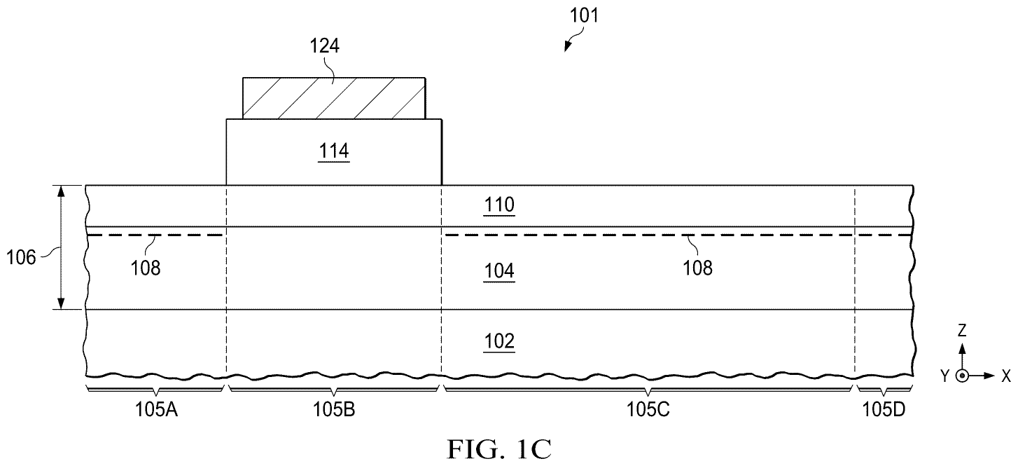

Referring to the drawings, FIG. 1A depicts a 3-dimensional (3D) schematic of a partially formed GaN device 101 including one or more tuning contacts or electrodes (e.g., providing capacitive loads for tuning threshold voltages) according to some examples of the present disclosure. FIGS. 1B and 1C depict cross-sectional views of the GaN device 101 along a first sectional plane through a gate and along a second sectional plane through an electrode operable as the tuning contact, respectively. Taking FIGS. 1A-1C together, set forth below is a configurable threshold voltage (V_{TH}) control arrangement with respect to the GaN device 101 according to some examples.

By way of illustration, the GaN device 101 may be fabricated as part of a semiconductor device 100, e.g., an IC device, formed on a portion of a semiconductor substrate 102. In some arrangements, the semiconductor substrate 102 may be provided as a silicon wafer, a silicon-on-sapphire wafer, or a silicon carbide wafer, and/or as semiconductor substrates including cores configured for matching coefficient of thermal expansion (CTE), and/or the like. A buffer layer 104 comprising one or more layers of III-N semiconductor material is formed on the substrate 102. In some examples where the substrate 102 is implemented as a silicon wafer or a sapphire wafer, the buffer layer 104 may include a nucleation layer having a stoichiometry that includes aluminum to match a lattice constant of the substrate 102. In some examples, the buffer layer 104 may further include layers/sublayers of aluminum gallium nitride (AlGaN) with decreasing aluminum content, including an unintentionally doped (UID) GaN sublayer in some arrangements—e.g., a topmost layer of the buffer layer 104. For purposes of the examples herein, the various layers/sublayers of a buffer layer, e.g., the buffer layer 104, are not specifically shown in the Figures of the present disclosure.

Depending on implementation, the buffer layer 104 may have a thickness of about 1 micron (μm) to several microns, e.g., 3.5 μm to 7.0 μm, which may be formed by a suitable epitaxial process, e.g., a metal organic vapor phase epitaxy (MOVPE) process with several sequential operations to form the various layers and/or sublayers. In some arrangements, an example buffer layer 104 may comprise a stack of multiple layers/sublayers of suitable materials and compositions (e.g., GaN, AlGaN) as noted above, where the layers/sublayers may have variable thicknesses depending on the technology and device application. In some arrangements, the buffer layer 104 may include AlGaN-based transition layers, epitaxial layers with strain-layer superlattice (SLS) structures, and the like.

The buffer layer 104 may be formed over an area of the substrate 102, where different regions such as a source region 105A, a gate region 105B, a drain region 105D and a drain access region 105C between the gate region 105B and the drain region 105D may be provided with respect to the GaN device 101. The source region 105A may be regarded as including a source access region (not specifically shown in the Figures), which may refer to a region between a source electrode and the gate region 105B similar to the drain access region 105C. A channel layer may be provided as part of the buffer layer 104—e.g., a top portion of the buffer layer 104 proximate to a barrier layer 110. Whereas a channel layer may primarily include GaN material, there may be optional trace amounts of other group III elements, such as aluminum or indium, in some implementations.

A barrier layer 110 comprising III-N semiconductor material is formed over the buffer layer 104 in a suitable epitaxy process. In an example arrangement, the barrier layer 110 may have a thickness ranging from about 1 nanometer (nm) to about 60 nm, and may include aluminum and nitrogen. In some versions of this example, the barrier layer 110 may include gallium at a lower atomic percent than aluminum. In some versions, the barrier layer 110 may also include indium. In some examples, the barrier layer 110 includes an AlGaN layer.

The barrier layer 110 over the buffer layer 104 is operable as part of a heterojunction structure 106 for causing the formation of a 2DEG 108 proximate to an interface between the barrier layer 110 and the buffer layer 104. In some examples, the stoichiometry and thickness of the barrier layer 110 may be configured to provide a suitable free charge carrier density (e.g., 3×10¹² cm⁻² to 2×10¹³ cm⁻²) of the 2DEG for facilitating the device operation.

For purposes of effectuating EMODE functionality, a p-doped III-N layer 114, e.g., comprising one or more layers of III-N material, is epitaxially formed over the barrier layer 110 as shown in FIGS. 1A-1C. In some examples, the p-doped III-N layer 114 may also be referred to as a p-III-N layer or a p-GaN layer. The formation of the p-GaN layer 114 causes the 2DEG to be reduced—e.g., absent in some cases. In versions of this example, the p-doped III-N layer 114 may comprise a GaN layer doped with magnesium (Mg) or other p-type dopants. In some examples, the p-doped GaN layer 114 may include a p-dopant concentration of about 1×10¹⁷ atoms/cm³ to 1×10²¹ atoms/cm³ and may have a thickness of about 10 nm to 200 nm. In some additional and/or alternative arrangements, additional layers such as an AlGaN cap layer (e.g., devoid of p-doping; not shown in the Figures) may be provided over the p-GaN layer 114.

For purposes of the present disclosure, the heterojunction structure 106 and the p-GaN layer 114 (and any AlGaN cap layers, if provided) may be collectively referred to as a p-doped III-N epi stack layer disposed over the semiconductor substrate 102. As will be set forth in detail further below, a same p-doped III-N epi stack layer over the semiconductor substrate 102 may be concurrently processed for fabricating multiple GaN devices having different V_{TH} values where the GaN devices may be separated by suitable isolation.

Although not specifically shown in separate process stages, the p-GaN layer 114 may be formed in the gate region 105B by patterning a p-GaN layer deposited over the heterojunction structure 106, where a suitable photolithography and plasma etch process may be used to form a part of a gate stack over the gate region 105B. In some examples where one or more capping layers (e.g., AlGaN layers and/or silicon nitride (SiN) layers) are provided over the p-GaN layer 114, the capping layers may also be patterned during the p-GaN etching process. A gate electrode 122 is subsequently formed over the p-GaN layer 114 (and additional capping layers if present), where the gate electrode 122 may have a preconfigured contact area based on applicable design rules. Depending on implementation, the gate electrode 122 may be formed before forming source and drain electrodes (not shown in FIGS. 1A-1C) in the source and drain regions 105A, 105D, respectively, in a process flow that may be referred to as a “gate first” process flow. In some additional/alternative examples, the gate electrode 122 may be formed after the source and drain electrodes in a process flow that may be referred to as a “gate last” process flow. As a result of patterning the p-GaN layer 114 (e.g., removing portions of the p-GaN layer 114 outside the gate region 105B), the 2DEG 108 may be established in the channel layer outside the gate region 105B.

In some versions of the examples herein, the source region 105A (where a source electrode or contact is be formed) and the drain region 105D (where a drain electrode or contact is to be formed) may be asymmetrically disposed relative to the gate region 105B although it is not a requirement. For example, there may be a greater lateral distance between the gate region 105B and the drain region 105D than a lateral distance between the gate region 105B and the source region 105A by virtue of an access region, e.g., drain access region 105C, disposed between the gate region 105B and the drain region 105D. In some additional and/or alternative arrangements, a source access region may also be provided between the source region 105A and the gate region 105B in a similar manner, as previously noted, while still having source/drain region asymmetry with respect to the gate region 105B.

Although not specifically shown in FIGS. 1A-1C, a suitable device isolation step may be implemented to achieve isolation with respect to the GaN device 101. Depending on implementation, an isolation step may be performed before patterning the p-GaN layer 114 or after patterning the p-GaN layer 114. In some arrangements, an isolation step may include mesa etching, implanting, etc., to define a region where the 2DEG 108 outside the active area associated with a GaN device, e.g., GaN device 101, is absent, eliminated or otherwise disrupted. In some examples, an Ar+ implant at 120 keV having a dosage around 5×10¹⁴ atoms/cm² may be implemented to achieve device isolation.

In some examples, one or more tuning electrodes 124 operable as capacitive loads are formed over the p-GaN layer 114 (and additional capping layers if present). In some examples, each tuning electrode 124 may have a respective contact area configured to modulate the threshold voltage of the GaN device 101 by counteracting the capacitance of the gate electrode 122 coupled to the channel of the GaN device 101 during device operation. Depending on implementation, the tuning electrodes 124 may be formed as Schottky electrodes that may be formed concurrently with the formation of source/drain electrodes in a GaN process flow, which may comprise a gate first flow or a gate last flow as previously noted. Accordingly, the tuning electrodes 124 may be formed after forming the gate electrode 122 or before forming the gate electrode 122 in some examples. Furthermore, the tuning electrodes 124 may be formed using different metallization schemes depending on implementation. In some arrangements, the tuning electrodes 124 may comprise contacts having metallization different than or same as the gate electrode metallization. In some arrangements, the tuning electrodes 124 may comprise contacts having metallization different than or same as the source/drain electrode metallization.

In some arrangements, the tuning electrodes 124 may be electrically connected to a reference node (V_{REF}), which may be an electrical ground or connected to a source voltage (V_{S}) applied to the source electrode. As a result, the tuning electrode 124 in conjunction with the p-GaN layer under the tuning electrode 124 may present an additional capacitance when the GaN device 101 is in operation, e.g., when a suitable gate voltage (V_{G}) is applied at the gate electrode 122. Accordingly, whereas the gate electrode 122 formed over the p-GaN layer 114 (and any additional capping layers if present) in one portion of the GaN device 101 (shown in the cross-sectional view of FIG. 1B) is operable to turn on the GaN device 101, the operation of the gate electrode 122 under the gate voltage (V_{G}) is counteracted by the additional capacitance biased to the source voltage (V_{S}) (or under a reference voltage (V_{REF}) different than V_{G}) such that the threshold voltage may increase. Such an increase in the threshold voltage may be regarded as a delay in turning on the channel under the gate stack—e.g., the gate voltage (V_{G}) needs to overcome the effect of the additional capacitance biased to either V_{S} or V_{REF}. Such an increase in the threshold voltage may be caused by reduced coupling between the gate stack (e.g., the gate electrode 122 and the p-GaN layer 114) and the channel layer 104 in the gate region, which is effectuated by the tuning electrode(s) 124 formed in another portion of the GaN device 101 (shown in the cross-sectional view of FIG. 1C). In some versions of this example, the increase in threshold voltage may be modulated or otherwise adjusted based on varying the capacitive load effect of the tuning electrodes 124 relative to the gate capacitance, where the capacitive load effect is in turn determined by the ratio of a total contact area of the tuning electrode(s) 124 to a gate contact area associated with the gate electrode 122.

Depending on application, a GaN device such as the GaN device 101 may be provided with a configurable number of tuning electrodes 124, where the number and/or total area of the tuning electrodes 124 may be varied relative to the area of the gate electrode 122 to achieve a desirable threshold voltage. In some examples, each tuning electrode 124 may have a respective contact area, which may be same or different. In some examples, the contact area of a tuning electrode 124 may be defined by a length TE_{L} and a width TE_{W}, which may be configured according to applicable design rules. Likewise, the contact area of the gate electrode 122 may be defined by a gate contact length G_{L} and a gate contact width G_{W}. Accordingly, the threshold voltage of the GaN device 101 in some examples may be configured and/or determined based on a ratio of contact areas given as Σ(TE_{L}xTE_{W})ᵢ/(GL_{L}GW_{W}, where i=the number of tuning electrodes.

In arrangements where the semiconductor device 100 comprises an IC that includes multiple GaN devices, each GaN device may be provided with a respective configuration of tuning electrodes by having a mask containing a variable tuning electrode pattern (number and/or contact area) for a given gate contact area with respect to each device depending on the desired V_{TH} value for that device. In examples where the tuning electrodes 124 are formed concurrently with the source/drain electrodes, a source/drain contact mask may accordingly be based on a layout design that includes appropriate tuning electrode patterns for each GaN device of the IC.

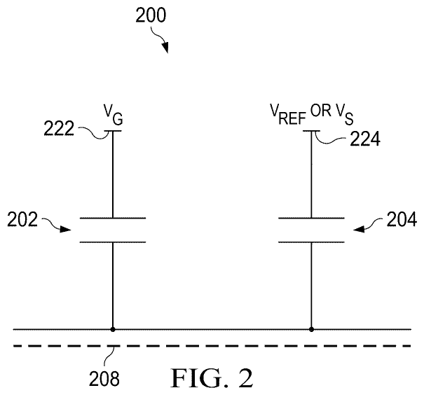

FIG. 2 depicts an equivalent circuit representation 200 of a GaN device, e.g., the GaN device 101, including one or more tuning electrodes that provides a threshold voltage tuning capacitive load according to some examples. In the example circuit representation 200, a gate capacitance 202 is driven by a V_{G} node 222 for turning on the GaN device by forming a completed 2DEG 208 in the channel layer of the GaN device. A tuning capacitive load 204 is representative of a total capacitive load presented by a plurality of tuning electrodes, e.g., tuning electrodes 124, where the tuning capacitive load 204 connected to a V_{REF} node 224 (or source voltage V_{S}) is operable to reduce the coupling effect of the gate capacitance 202 with respect to the 2DEG 208, thus resulting in an increased V_{TH.}

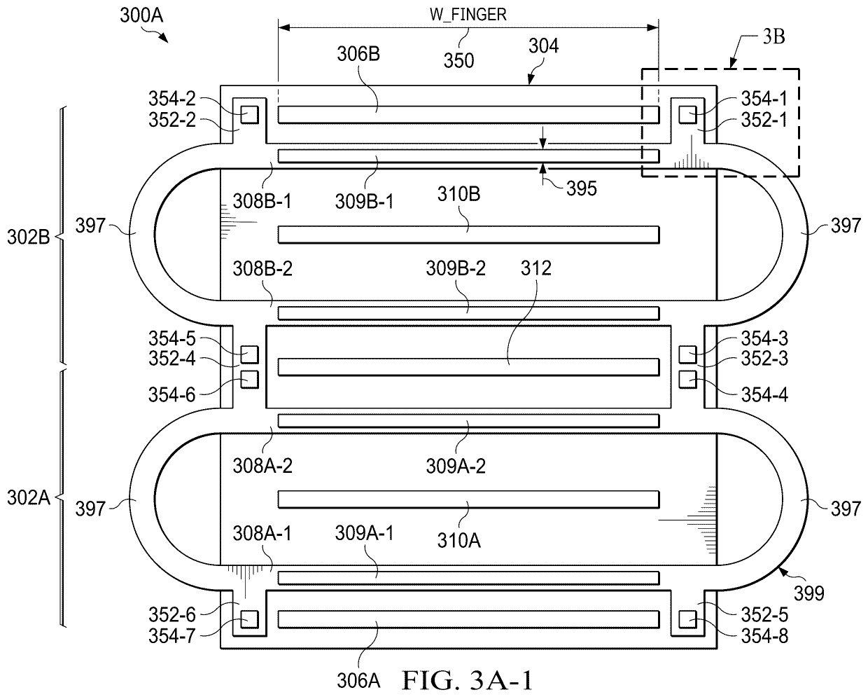

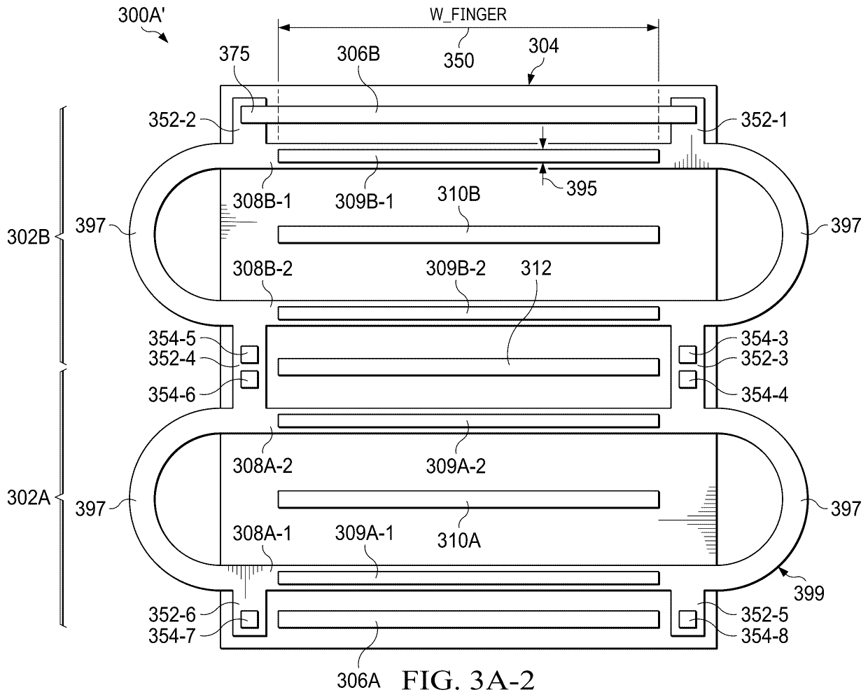

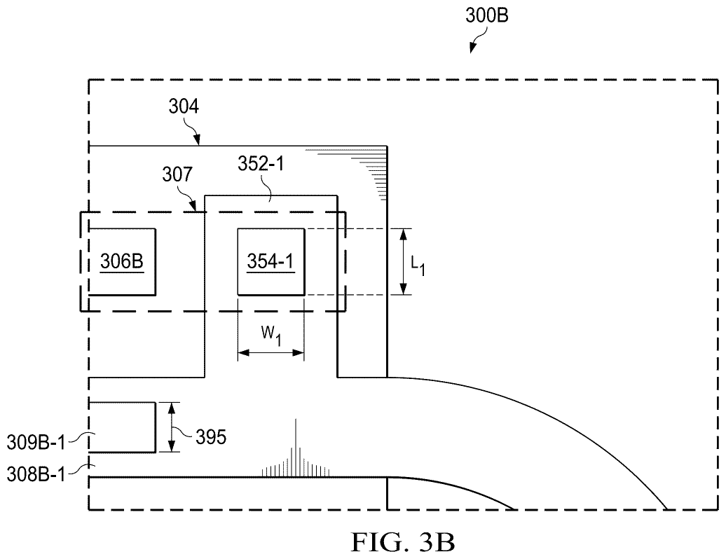

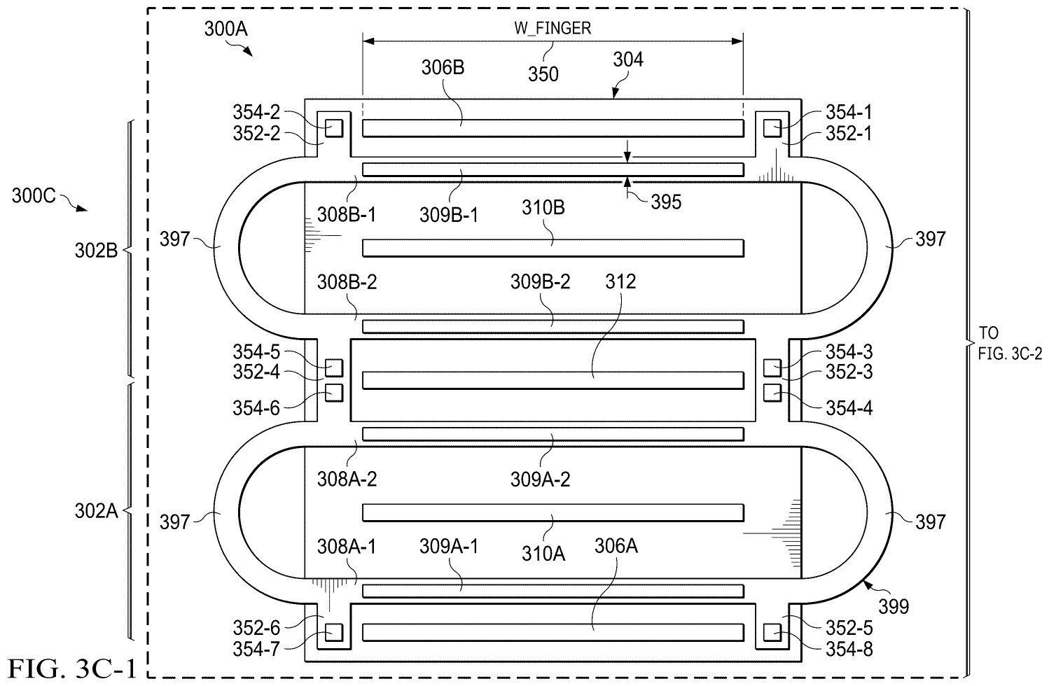

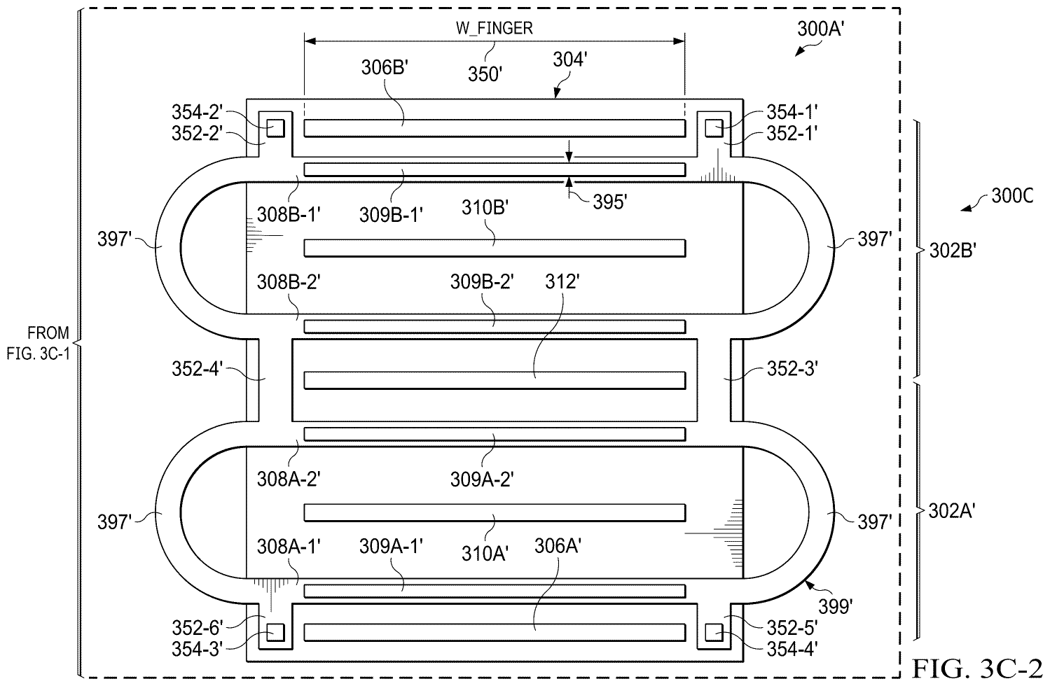

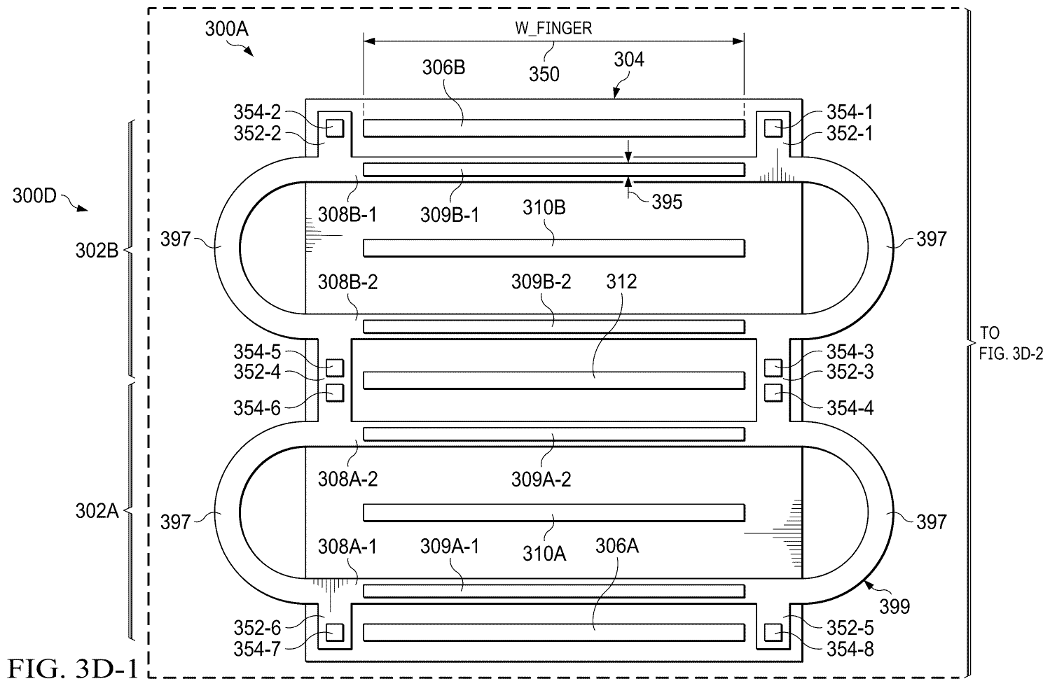

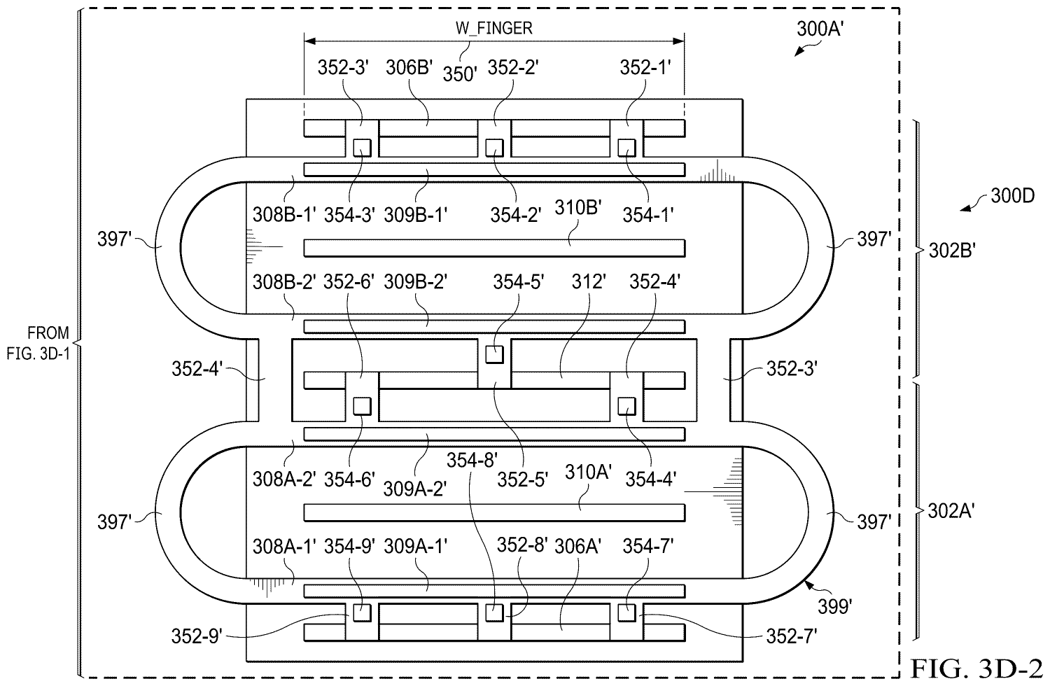

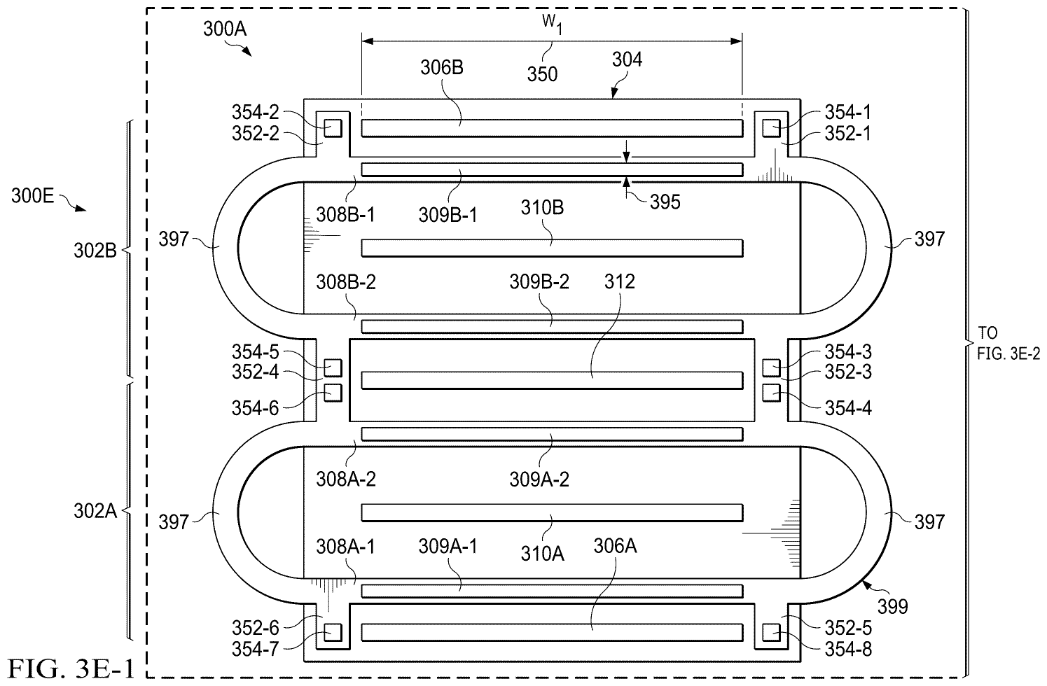

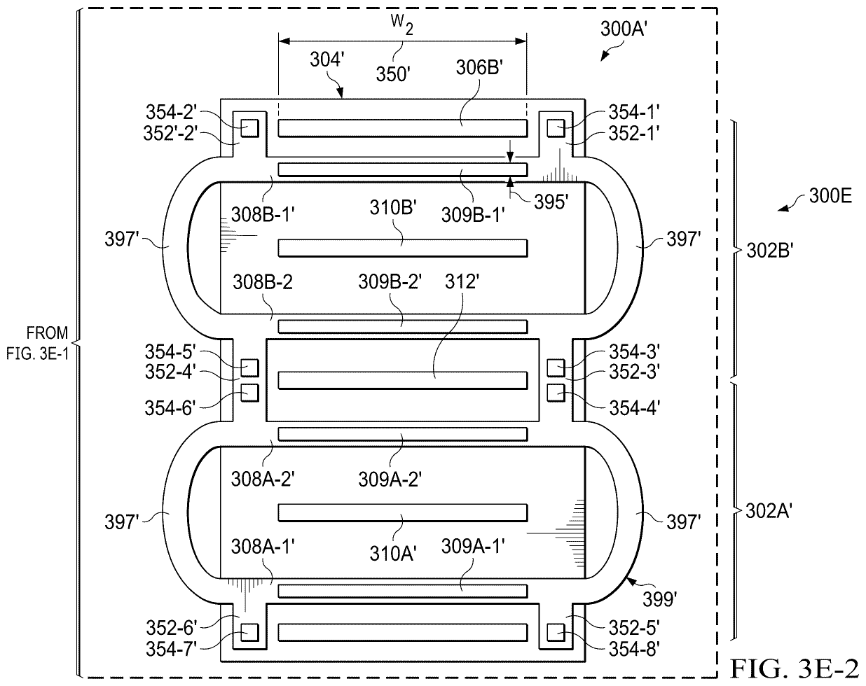

FIG. 3A-1 depicts a representative layout of a GaN device where one or more tuning electrodes may be provided in a configurable architecture for tuning the threshold voltage of the GaN device according to some examples. Without limitation, a drain-centered two-finger layout of a GaN device 300A is shown in FIG. 3A-1, where a first finger 302A and a second finger 302B are formed in or over an active region 304 defined by an isolation boundary. In some examples, the active region 304 may be formed as part of a common III-N epi stack layer configured to support multiple GaN devices separated by isolation regions in a semiconductor IC device. As a drain-centered design, an example layout for a finger may include a source, a drain, and a gate formed in a region between the source and drain, where a p-GaN layer (and any additional capping layers such as AlGaN layers, SiN layers, if present) may be patterned to form a racetrack or obround structure surrounding the drain. Accordingly, as shown in FIG. 3A-1, the first finger 302A includes a drain 310A, a source 306A and a source 312 common to the first and second fingers 302A and 302B. In similar fashion, the second finger includes a drain 310B, a source 306B and the common source 312. A p-GaN layer 399 may be patterned to include p-GaN portions 308A-1 and 308A-2 with respect to the first finger 302A and p-GaN portions 308B-1 and 308B-2 with respect to the second finger 302A.

In some implementations, the p-GaN portions 308A-1 and 308A-2 as well as the p-GaN portions 308B-1 and 308B-2 may be coupled to each other by respective arcuate portions 397 for forming a closed-loop racetrack structure with respect to each finger. In this manner, the p-GaN may form the closed-loop racetrack structure surrounding the respective drain 310A, 310B. In some implementations, the arcuate portions 397 may extend across the isolation boundary, although such an arrangement is not a requirement. For example, the p-GaN layer 399 of the two-finger GaN device 300A may lie entirely within the active region 304 in some implementations. Further, the p-GaN layer 399 may not form a continuous structure in some additional and/or alternative arrangements (e.g., without the arcuate portions 397 respectively connecting the p-GaN portions 308A-1 and 308A-2 and/or the p-GaN portions 308B-1 and 308B-2). Regardless of how a p-GaN layer is laid out in a particular design, the p-GaN layer 399 may be provided with one or more portions, tabs, extensions, other features, etc. disposed over the active region 304 at appropriate locations of the GaN device 300A for facilitating the formation of one or more tunable electrodes as will be set forth below.

In some arrangements, suitable gate contact areas may be defined with respect to each finger 302A, 302B, where a gate contact area may be determined by a width 350 of the fingers 302A, 302B and a gate length 395. As illustrated, gate contact areas 309A-1 and 309A-2 are shown with respect to the first finger 302A and gate contact areas 309B-1 and 309B-2 are shown with respect to the second finger 302B. To facilitate the formation of tuning electrodes, the p-GaN layer 399 of the GaN device 300A is provided with p-GaN extensions 352-1 to 352-6, where the extensions 352-1 and 352-2 are associated with the second finger 302B and the extensions 352-5 and 352-6 are associated with the first finger 302A, with the extensions 352-3 and 352-4 being common to the fingers 302A and 302B. Although the representative layout of the GaN device 300A is illustrated with p-GaN extensions provided at or proximate to respective terminal portions of the fingers 302A, 302B (hence proximate to the terminal portions of the respective sources 306A, 306B, 312, such an arrangement is not a requirement. In additional and/or alternative layout designs, the p-GaN extensions 352-1 to 352-6 may comprise fewer or more extensions and/or may be provided at other locations of the layout as long as the extensions are positioned within the active area 304. Further, the size and/or shape of the p-GaN extensions may also vary as long as each extension has an appropriate size and/or shape configured to facilitate the formation of a tuning electrode having a suitable contact area while satisfying applicable critical dimension (CD) design rules.

In the example of FIG. 3A-1, the p-GaN extension 352-1 extending from the p-GaN portion 308B-1 of the second finger 302B is shown with a contact area 354-1 for forming a tuning electrode, such as the tuning electrode 124 depicted in FIG. 1A. In similar fashion, contact areas 354-2 through 354-8 are illustrated for forming a total of eight tuning electrodes with respect to the GaN device 300A. As previously noted, tuning electrodes may be electrically connected to a source for operating as capacitive loads during device operation in some examples. Accordingly, a source/drain contact metal layer extending to the tuning electrode contact areas may be provided in an example implementation.

FIG. 3B depicts a layout detail of a tuning electrode commonly connected to a source of the GaN device 300A shown in FIG. 3A-1. As illustrated in FIG. 3B, the p-GaN tab 352-1 forming an extension of the p-GaN portion 308B-1 of the second finger 302B is provided with the tuning electrode contact area 354-1 having a width W₁ and a length L₁. A source/drain metal contact layer 307 extends over the tuning electrode contact area 354-1, thus resulting in a common electrical connection with the source 306B of the GaN device 300A after completion of fabrication.

In some additional and/or alternative arrangements, the layout of an example GaN device may include a contact design where a p-GaN extension for forming a tuning electrode may be connected to a source region by a source contact extending to the p-GaN extension rather than the p-GaN extension having a separate contact as shown in the example of FIG. 3A-1 described above. For purposes of some examples, a design where a source contact is extended to a p-GaN extension for facilitating the formation of tuning electrode(s) may be referred to as a continuous source contact design. By way of illustration, FIG. 3A-2 depicts an example layout of a two-finger GaN device 300A′, analogous to the GaN device 300A, where a continuous source contact 375 is provided for connecting the p-GaN extensions 352-1 and 352-2 to the source 306B. Although a single continuous source contact 375 is illustrated in FIG. 3A-2, it is not a limitation, and one or more continuous source contacts may be provided in the layout of a GaN device according to some versions of this example. Further, an example implementation may include a layout design where both separate contacts and continuous source contacts may be provided with respect to forming tuning electrodes for a GaN device, e.g., the GaN device 300A′, as illustrated in FIG. 3A-2.

As previously noted, the number and/or contact area(s) of tunable electrodes may be independently configured relative to the gate contact area for each GaN device of a semiconductor IC device depending on the desired threshold voltages with respect to the GaN devices. In some arrangements, a semiconductor IC device comprising multiple GaN devices may include one or more GaN devices without tunable electrodes (which may be considered a “default” device configuration where there is no counteracting capacitive loading effect in the gate operation, thus resulting in a “baseline” V_{TH} value) and one or more GaN devices with various tunable electrode arrangements configured to provide a range of V_{TH} increase, hence a corresponding range of V_{TH} values that are greater than the baseline V_{TH.}

In some related versions, a semiconductor IC device may comprise one or more GaN devices where a first group of the GaN devices may each have a first number of tunable electrodes while a second group of the GaN device may each have a second number of tunable electrodes that may be same or different from the first number of tunable electrodes. In some related versions, the first number of tunable electrodes may each have a first contact area and the second number of tunable electrodes may each have a second contact area that is same or different from the first contact area. In some further related versions, a semiconductor IC device may comprise one or more GaN devices where a first group of the GaN devices may each have a gate electrode having a first gate contact area while a second group of the GaN devices may each have a gate electrode having a second gate contact area that may be same or different from the first gate contact area.

FIGS. 3C-1 and 3C-2, 3D-1 and 3D-2, and 3E-1 and 3E-2 depict various layouts of GaN devices according to some additional and/or alternative examples of the present disclosure. According to one implementation, FIGS. 3C-1 and 3C-2 taken together depict a layout of a representative semiconductor IC device 300C comprising two GaN devices where one GaN device includes a first number of tuning electrodes while a second GaN device includes a second number of tuning electrodes. As illustrated in FIG. 3C-1, a first GaN device comprising the GaN device 300A described above may be provided as part of the semiconductor IC device 300C where a layout including eight tuning electrode contact areas 354-1 to 354-8 is provided for configuring the threshold voltage of the GaN device 300A as set forth previously. As illustrated in FIG. 3C-2, another drain-centered two-finger GaN device 300A′, analogous to the GaN device 300A, is provided as a second GaN device where the constituent components are essentially similar to the corresponding components of the GaN device 300A except that a different number of tuning electrodes (e.g., four (4) tuning electrodes) may be provided as noted herein. Accordingly, like components in the second GaN device 300A′ are denoted with the same reference number or initialism as corresponding components in the GaN device 300A, but with an apostrophe (') appended thereto, including any alphabetical designations as applicable.

In one example, the GaN devices 300A and 300A′ are formed in respective active regions 304, 304′ of the IC device 300C separated by appropriate isolation—e.g., mesa etching, Ar+ implant, etc., as noted previously. GaN devices 300A, 300A′ may include epi stacks formed from a same III-N stack layer over a semiconductor substrate, where the III-N stack layer is demarcated by respective isolation boundaries in some arrangements, e.g., as a first stack of III-N layer and a second stack of III-N layer. In some arrangements, the first stack of III-N layer and the second stack of III-N layer may be formed concurrently. Whereas the first GaN device 300A includes eight tuning electrode contact areas 354-1 to 354-8 formed over corresponding p-GaN extensions 352-1 to 352-6 located at or proximate to respective terminal portions of the two fingers 302A, 302B, the second GaN device 300A′ includes four tuning electrode contact areas 354-1′ to 354-4′ over corresponding p-GaN extensions 352-1′, 352-2′, 352-5′ and 352-6′ located at or proximate to respective terminal portions of the two fingers 302A′ and 302B′. Further, the contact areas 354-1 to 354-8 may have form factors that are same as or different from form factors of the contact areas 354-1′ to 354-4′ in some examples.

Because of concurrent processing of the GaN devices 300A, 300A′, a gate stack of the first GaN device 300A and a gate stack of the second GaN device 300A′ include the same components, respectively. Accordingly, the gate stack of the first GaN device 300A includes a gate electrode over the p-GaN layer that is identical to the gate stack of the second GaN device 300A′, respective gate stacks being formed over respective heterojunction structures including the same layers (e.g., barrier layer 110 and buffer layer 104), although the first and second GaN devices 300A, 300A′ may have different V_{TH} values because of the different tuning electrode configurations.

FIGS. 3D-1 and 3D-2 taken together depict a layout of a representative semiconductor IC device 300D comprising two GaN devices 300A and 300A′ according to an example where a second GaN device 300A′ is substantially similar to the first GaN device 300A described above except that one or more tuning electrode contact areas 354-1′ to 354-9′ are formed over respective p-GaN extensions 352-1′ to 352-9′ extending over a channel region, e.g., between a gate and a source. By way of example, p-GaN extensions 352-1′ to 352-3′ extend from the p-GaN portion 308B-1′ and over the source 306B′, where the p-GaN extensions 352-1′ to 352-3′ are operable to support tuning electrodes 354-1′ to 354-3′.

FIGS. 3E-1 and 3E-2 taken together depict a layout of a representative semiconductor IC device 300E comprising two GaN devices 300A and 300A′ according to an example where a second GaN device 300A′ is substantially similar to the first GaN device 300A described above except that finger widths of the two devices 300A and 300A′ are different. As illustrated, the first GaN device 300A comprises two fingers 302A, 302B having a first width (W₁), whereas the second GaN device 300A′ comprises fingers 302A', 302B′ having a second width (W₂) less than W₁. Accordingly, the gate widths (and channel widths) of the fingers 302A', 302B′ of the second GaN device 300A′ are also less than gate widths (and channel widths) of the fingers 302A, 302B of the first GaN device 300A. Because the gate widths may not substantially affect the threshold voltage of a GaN device, GaN devices 300A, 300A′ may have substantially similar V_{TH} values unless the respective tunable electrode configurations are modified in some fashion. For example, the first and second GaN devices 300A, 300A′ may have a different number of tuning electrodes and/or have tuning electrodes with different contact areas, which can operate to reduce the coupling of gate capacitance to the channel layer in the respective devices in a differential manner, thus leading to different V_{TH} values. In some arrangements, there may be area ratio differences between the GaN devices 300A, 300A′ even where the number and/or contact area of the tuning electrodes of the GaN devices 300A, 300A′ is the same because of the different gate widths, resulting in different V_{TH} values accordingly.

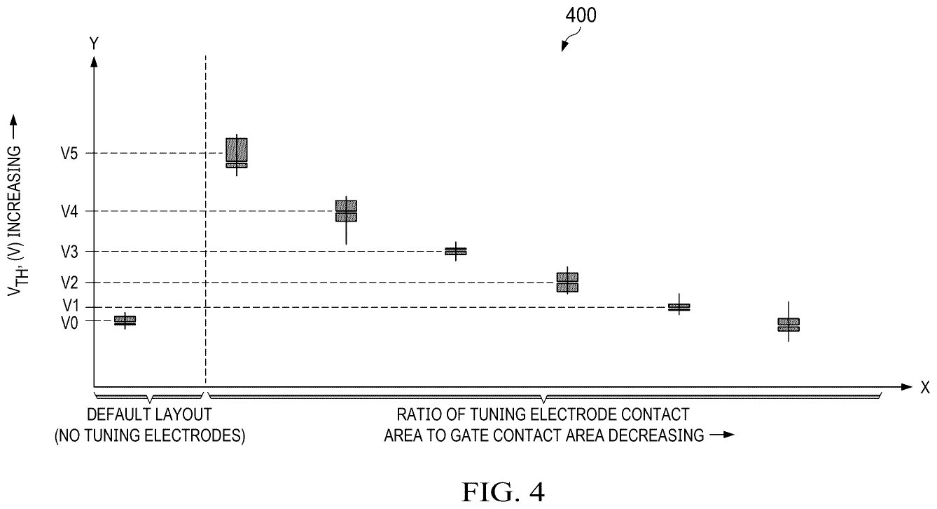

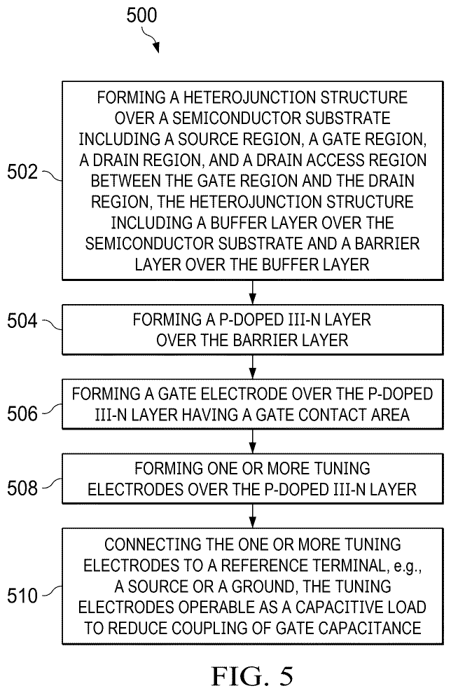

As described herein, one or more tunable electrodes may operate to counteract the coupling effect of gate capacitance in a GaN device. As such, an overall area of tunable electrodes relative to the gate contact area (which in turn is dependent on the device finger width in some implementations) may determine amount of increase in the V_{TH} values. FIG. 4 depicts a graph 400 illustrating a relationship between GaN V_{TH} values, plotted on Y-axis, and the ratio of tuning electrode contact area to gate contact area of the GaN device, plotted on X-axis. As illustrated, GaN devices with a default layout design (e.g., having no tuning electrodes) have V_{TH} values (for a given drain voltage V_{D}) that are lower than V_{TH} values of GaN devices with one or more tuning electrodes (at corresponding drain voltages). As the effect of tuning electrodes diminishes with a decreasing ratio of the tuning electrode contact area to the gate contact area, the V_{TH} values correspondingly trend lower, eventually reaching values that are similar to the baseline V_{TH} values associated with the default GaN layout design in some examples.

FIG. 5 is a flowchart of a method of fabricating a semiconductor device including one or more GaN devices according to some examples of the present disclosure. In one arrangement, method 500 may commence with forming a heterojunction structure over a semiconductor substrate including a source region, a gate region, a drain region, and a drain access region between the gate region and the drain region, as set forth at block 502. As previously noted, the heterojunction structure may include a buffer layer over the semiconductor substrate and a barrier layer over the buffer layer. At block 504, a p-doped III-N layer may be formed over the barrier layer. As previously noted, one or more capping layers, e.g., AlGaN layers, may be optionally formed over the p-doped III-N layer in some arrangements. Regardless of whether a capping layer is provided, the p-doped III-N layer, the barrier layer and the buffer layer may be formed as part of a single III-N epi stack layer over the semiconductor substrate operable to support multiple active regions separated by isolation. At block 506, a gate electrode may be formed over the p-doped III-N layer having a gate contact area. At block 508, one or more tuning electrodes may be formed over the p-doped III-N layer depending on a desired V_{TH} value. At block 510, the tuning electrodes may be connected to a reference terminal, e.g., a source or a ground, or to a terminal having a voltage different than the gate voltage, where the tuning electrodes are operable as a capacitive load to reduce coupling of gate capacitance to the channel layer so to achieve the desired V_{TH} value.

In some arrangements, the formation of a p-doped III-N layer may include patterning the p-doped III-N layer to include one or more extensions, tabs, etc., for supporting the formation of tuning electrodes at appropriate locations of a layout design. In some arrangements, the tuning electrodes may be formed concurrently with formation of source and drain electrodes in the source and drain regions, respectively, using a single source/drain contact mask including a suitable tuning electrode contact area pattern. In some arrangements, the source/drain electrodes may be formed before or after forming the gate electrode as noted previously. Additional details regarding the formation of gate and source/drain electrodes in a gate first flow or a gate last flow may be found in the following U.S. Patent Applications: (i) Application No. Ser. No. 18/756,202, filed Jun. 27, 2024; and (ii) Application No. Ser. No. 18/788,650, filed Jul. 30, 2024; each of which is incorporated by reference herein in its entirety for all purposes.

While various examples of the present disclosure have been described above, they have been presented by way of example only and not limitation. Numerous changes to the disclosed examples can be made in accordance with the disclosure herein without departing from the spirit or scope of the disclosure. Thus, the breadth and scope of the present disclosure should not be limited by any of the above described examples. Rather, the scope of the disclosure should be defined in accordance with the claims appended hereto and their equivalents.

For example, in this disclosure and the claims that follow, unless stated otherwise and/or specified to the contrary, any one or more of the layers set forth herein can be formed in any number of suitable ways, such as with spin-on techniques, sputtering techniques (e.g., Magnetron and/or ion beam sputtering), (thermal) growth techniques or deposition techniques such as chemical vapor deposition (CVD), physical vapor deposition (PVD), PECVD, or atomic layer deposition (ALD), etc. As another example, silicon nitride may be a silicon-rich silicon nitride or an oxygen-rich silicon nitride. Silicon nitride may contain some oxygen, but not so much that the materials dielectric constant is substantially different from that of high purity silicon nitride.

Further, in at least some additional or alternative implementations, the functions/acts described in the blocks may occur out of the order shown in the flowcharts. For example, two blocks shown in succession may in fact be executed substantially concurrently or the blocks may sometimes be executed in the reverse order, depending upon the functionality/acts involved. Moreover, the functionality of a given block of the flowcharts and/or block diagrams may be separated into multiple blocks and/or the functionality of two or more blocks of the flowcharts and/or block diagrams may be at least partially integrated. Also, some blocks in the flowcharts may be optionally omitted. Furthermore, although some of the diagrams include arrows on communication paths to show a primary direction of communication, it is to be understood that communication may occur in the opposite direction relative to the depicted arrows. Finally, other blocks may be added/inserted between the blocks that are illustrated.

The order or sequence of the acts, steps, functions, components or blocks illustrated in any of the flowcharts and/or block diagrams depicted in the drawing Figures of the present disclosure may be modified, altered, replaced, customized or otherwise rearranged within a particular flowchart or block diagram, including deletion or omission of a particular act, step, function, component or block. Moreover, the acts, steps, functions, components or blocks illustrated in a particular flowchart may be inter-mixed or otherwise inter-arranged or rearranged with the acts, steps, functions, components or blocks illustrated in another flowchart in order to effectuate additional variations, modifications and configurations with respect to one or more processes for purposes of practicing the teachings of the present disclosure. Likewise, although various examples have been set forth herein, not all features of a particular example are necessarily limited thereto and/or required therefor.

At least some portions of the foregoing description may include certain directional terminology, such as, “upper”, “lower”, “top”, “bottom”, “left-hand”, “right-hand”, “front side”, “backside”, “vertical”, “horizontal”, etc., which may be used with reference to the orientation of some of the Figures or illustrative elements thereof being described. Because components of some examples can be positioned in a number of different orientations, the directional terminology is used for purposes of illustration and is in no way limiting. Likewise, references to features referred to as “first”, “second”, etc., are not indicative of any specific order, importance, and the like, and such references may be interchanged, depending on the context, implementation, etc. In addition, terms such as “over”, “under”, “below”, etc., relative to the spatial orientation of two components does not necessarily mean that one component is immediately or directly over the other component, or that one component is immediately or directly under or below the other component. Further, the features and/or components of examples described herein may be combined with each other unless specifically noted otherwise.

Although various implementations have been shown and described in detail, the claims are not limited to any particular implementation or example. None of the above Detailed Description should be read as implying that any particular component, element, step, act, or function is essential such that it must be included in the scope of the claims. Where the phrases such as “at least one of A and B” or phrases of similar import are recited or described, such a phrase should be understood to mean “only A, only B, or both A and B. ” Reference to an element in the singular is not intended to mean “one and only one” unless explicitly so stated, but rather “one or more. ” In similar fashion, phrases such as “a plurality” or “multiple” may mean “one or more” or “at least one”, depending on the context. All structural and functional equivalents to the elements of the above-described implementations are expressly incorporated herein by reference and are intended to be encompassed by the claims appended below.

What is claimed is:

1. A semiconductor device, comprising:
a semiconductor substrate including a source region, a gate region, a drain region, and a drain access region between the gate region and the drain region;
a heterojunction structure over the semiconductor substrate, the heterojunction structure including a buffer layer over the semiconductor substrate and a barrier layer over the buffer layer;
a p-doped III-N layer over the barrier layer;
one or more tuning electrodes over the p-doped III-N layer; and
a gate electrode over the p-doped III-N layer having a gate contact area.

2. The semiconductor device of claim 1, wherein the one or more tuning electrodes comprise a preconfigured number of tuning electrodes based on a threshold voltage of the semiconductor device.

3. The semiconductor device of claim 1, wherein each tuning electrode has a contact area and a threshold voltage of the semiconductor device is determined based on a ratio of a total contact area of the one or more tuning electrodes to the gate contact area.

4. The semiconductor device of claim 1, wherein the one or more tuning electrodes are connected to the source region.

5. The semiconductor device of claim 1, wherein the one or more tuning electrodes are connected to a reference terminal.

6. The semiconductor device of claim 1, wherein each tuning electrode of the one or more tuning electrodes has a same contact area.

7. The semiconductor device of claim 1, wherein the one or more tuning electrodes have different contact areas.

8. The semiconductor device of claim 1, wherein at least one tuning electrode of the one or more tuning electrodes is formed over a corresponding p-doped III-N tab of the p-doped III-N layer, the p-doped III-N tab extending from the p-doped III-N layer proximate to a terminal portion of the source region.

9. The semiconductor device of claim 1, wherein at least one tuning electrode of the one or more tuning electrodes is formed over a corresponding p-doped III-N tab of the p-doped III-N layer, the p-doped III-N tab extending from the p-doped III-N layer over the source region.

10. The semiconductor device of claim 1, further comprising an AlGaN cap layer over the p-doped III-N layer.

11. The semiconductor device of claim 1, wherein the one or more tuning electrodes and a source electrode in the source region include a same material.

12. The semiconductor device of claim 1, wherein the one or more tuning electrodes and the gate electrode include a same material.

13. A method of fabricating a III-N semiconductor device, comprising:
forming a heterojunction structure over a semiconductor substrate including a source region, a gate region, a drain region, and a drain access region between the gate region and the drain region, the heterojunction structure including a buffer layer over the semiconductor substrate and a barrier layer over the buffer layer;
forming a p-doped III-N layer over the barrier layer;
forming a gate electrode over the p-doped III-N layer having a gate contact area; and
forming one or more tuning electrodes over the p-doped III-N layer.

14. The method of claim 13, wherein the gate electrode is formed before forming source and drain electrodes in the source and drain regions, respectively.

15. The method of claim 13, wherein the gate electrode is formed after forming source and drain electrodes in the source and drain regions, respectively.

16. The method of claim 13, wherein the one or more tuning electrodes are formed during formation of source and drain electrodes in the source and drain regions, respectively.

17. The method of claim 13, wherein the one or more tuning electrodes and the gate electrode are formed with a same material.

18. The method of claim 13, further comprising connecting the one or more tuning electrodes to the source region or to a reference node.

19. The method of claim 13, further comprising forming an AlGaN cap layer over the p-doped III-N layer.

20. An integrated circuit (IC), comprising:
a semiconductor substrate;
a first III-N device formed in or over a first area of the semiconductor substrate, the first III-N device including:
a source region and a gate region of the first area;
a first stack of III-N layer including a first heterojunction structure and a first p-doped III-N layer formed on the first heterojunction structure;
a gate electrode having a first gate contact area disposed over the first p-doped III-N layer; and
a first number of tuning electrodes over the first p-doped III-N layer; and
a second III-N device formed in or over a second area of the semiconductor substrate, the second III-N device including:
a source region and a gate region of the second area;
a second stack of III-N layer including a second heterojunction structure and a second p-doped III-N layer formed on the second heterojunction structure;
a gate electrode having a second gate contact area disposed over the second p-doped III-N layer; and
a second number of tuning electrodes over the second p-doped III-N layer.

21. The IC of claim 20, wherein:
the first number of tuning electrodes is zero; and
the second number of tuning electrodes is not zero.

22. The IC of claim 20, wherein the first number of tuning electrodes and the second number of tuning electrodes are same.

23. The IC of claim 20, wherein the first number of tuning electrodes and the second number of tuning electrodes are different.

24. The IC of claim 20, wherein the first gate contact area and the second gate contact area are same.

25. The IC of claim 20, wherein the first gate contact area and the second gate contact area are different.

26. The IC of claim 20, wherein:
the first heterojunction structure includes a first buffer layer over the semiconductor substrate and a first barrier layer on the first buffer layer; and
the second heterojunction structure includes a second buffer layer over the semiconductor substrate and a second barrier layer on the second buffer layer.

27. The IC of claim 20, wherein the first stack of III-N layer and the second stack of III-N layer are formed concurrently.

28. The IC of claim 20, wherein:
the first III-N device has a first channel width; and
the second III-N device has a second channel width different than the first channel width.
